(19) United States
(12) Patent Application Publication
(10) Pub. No.: US 2009/0133852 A1
(43) Pub. Date: May 28, 2009

(54) COOLING APPARATUS FOR ELECTRONIC EQUIPMENT

(76) Inventors: Kenji Ogiro, Yokohama (JP); Nobuo Masuoka, Chigasaki (JP); Takeshi Hizono, Yokohama (JP); Kenichi Shiode, Machida (JP)

Correspondence Address: ANTONELLI, TERRY, STOUT & KRAUS, LLP, 1300 NORTH SEVENTEENTH STREET, SUITE 1800, ARLINGTON, VA, 22209-3873, US

(21) Appl. No.: 12/260,110

(22) Filed: Oct. 29, 2008

(30) Foreign Application Priority Data
Nov. 27, 2007 (JP) 2007-305200

(51) Int. Cl. F28F 7/00; H05K 7/20

(52) U.S. Cl. 165/80.3; 361/690

(57) ABSTRACT

A cooling apparatus for use in electronic equipment, being small in sizes and simple in the structures thereof, for achieving an increasing cooling capacity, comprises: a heat receiving member, which is thermally connected with a heat generating body, and which is configured to receive heat by means of a coolant flowing within an inside thereof; and a heat radiating member, which is configured to radiate the heat received within the heat receiving member, wherein the heat receiving member has a plate-like heat receiving base body, which is thermally connected with the heat generating body, and a heat receiving case body, which covers over the heat receiving base body, wherein the body members are joined with, so as to define a sealed space for running the coolant therein. The heat receiving base body is a plate-like member, being made of a metallic material, and being formed with fins, as a unit, for building up flow passages of the coolant, on a plane thereof on a side opposite to a plane, which is thermally connected with the heat generating body. The heat receiving case body is formed with a flow inlet and a flow outlet for running the coolant therein and out, on an upper surface or a side surface thereof, and a plural number of flange-like attaching portions extending nearly perpendicular to the side surface at a lower end portion of the side surface, as a unit. And, the heat receiving member is held opposite to the heat generating body of the electronic equipment, and is thermally connected with the heat generating body, by pressing the heat receiving member onto the heat generating body through an elastic deformation within the attaching portions of the heat receiving case body and the heat receiving case body, thereby achieving the thermal connection therebetween.

### BACKGROUND OF THE INVENTION

The present invention relates to a cooling apparatus for a heat generating body or element within electronic equipment, and in particular, it relates to the structures of a heat receiving member for thermally connecting with the heat generating body.

In general, the electronic equipment has a semiconductor integrated circuit therein, such as, a CPU, representatively, for example. This semiconductor integrated circuit is highly integrated, rapidly, for meeting small-sizing and high-functioning thereof, and accompanying with that increases the heating value (calorific value) thereof. The semiconductor integrated circuit, if being equal or higher than a predetermined temperature, not only unable to maintain the performances owned therewith, but also is broken. Therefore, for the semiconductor integrated circuit, there is necessity of cooling to suppress the temperature from increasing, and is required a cooling capacity of high performance.

On the other hand, the electronic equipments are remarkable, in particular, in tendency or trend of small and thin sizing thereof, because of also spreading of portable-type products, etc., and since they are under the condition that a mounting space for the cooling apparatus is limited, greatly, therefore, there are also required structures of being small and simple, for the cooling apparatus for use in the electronic equipments.

In recent years, for dealing with those problems, as the cooling apparatus within the electronic equipments is made the study on a liquid cooling method, in the place of the air cooling method. The cooling capacity of the liquid cooling method is superior, in particular, the heat transfer coefficient of a cooling liquid (i.e., a coolant), to that of the air, but the heat transfer coefficient can be influenced by the thermal connecting condition of a heat receiving member lying between the heat generating body and the coolant, and therefore the thermal connecting structure of the heat receiving member is important.

As a technology for achieving an improvement of the heat transfer coefficient of the heat receiving member within the cooling apparatus of the liquid cooling method, for example, in the following Patent Document 1 is disclosed a technology of controlling the suppressing direction of the heat receiving member, and also a technology of suppressing heat transfer loss of a heat transfer grease is disclosed in the following Patent Document 2.

Although relating to the cooling apparatus of the air cooling method, however in the following Patent Document 3 is disclosed a basic structure for achieving thermal connection between the heat generating body and a heat sink, by means of a spring power. And also, in the following Patent Document 4 is disclosed a technology of applying elastic deformation onto the fixing structure of the heat sink.

[Patent Document 1] Japanese Patent Laying-Open No. 2006-287149 (2006);

[Patent Document 2] Japanese Patent Laying-Open No. 2006-332148 (2006);

[Patent Document 3] Japanese Patent Laying-Open No. 2001-24114 (2001); and

[Patent Document 4] Japanese Patent Laying-Open No. 2005-38871 (2005).

A heat radiating apparatus described in the Patent Document 1, for the purpose of increasing the cooling capacity with increasing the contact (i.e., tightness) between a pump having a heat receiving member as a unit (hereinafter, being called “heat receiving unit pump”), and the heat generating body, such as, a CPU, etc., has such structure: the heat receiving unit pump is held in parallel with an upper surface of the CPU by a fixing tool with using pressing power of a coil spring. However, with the technology described in the Patent Document 1, because it needs the fixing tool having a shape for covering the heat receiving member and the coil spring for pressing the fixing tool, and further needs a space for mounting those, therefore it is difficult to achieve the small-sizing of the electronic equipments.

The cooling apparatus described in the Patent Document 2 adopts such structures that: i.e., for the purpose of increasing the cooling capacity or performance by reducing the heat resistance of the heat conductive grease, which is put between both members so as to achieve the thermal contact, i.e., the heat generating member and the heat absorber, the heat conductive grease is thinned in the thickness thereof, uniformly, by means of a cam mechanism for achieving relative sliding movement of a pressing/sliding apparatus, when holding a heat absorber on the heat generating body, with pressing thereon. However, the technology described in the Patent Document 2 needs the cam mechanism for building up the pressing/sliding apparatus, and also the coil spring for applying the pressing power or force, therefore results in the complex structures, and with this, it is impossible to achieve the small-sizing of the electronic equipments.

With the heat sink described in the Patent Document 3, a main body of the heat sink is held, but freely enabling up and down movement, as well as, freely inclining, and the main body of the heat sink biased towards a MPU by means of the coil spring. With this, the heat sink can be certainly contact with the heat generating surface of the MPU. However, the technology of the Patent Document 3 is limited only to a case, where a heat receiving surface is small and the heat sink has no deformation thereof, for dealing with the deformation of a PC panel or plate. On the contrary, there is a possibility of generating a deformation and/or an inclination, etc., of the PC panel or plate, newly, due to the difference in the spring force of the coil spring, etc., when it is in the attached condition.

The heat sink described in the Patent Document 4 is made from a plate-like member having a heat radiation fins, being provided with an opening or a cut, etc., as an elastic force imparting means, and the plate-like member is fixed on the heat generating element, pressing it by elastically or deforming the plate-like member. However, with the technology described in the Patent Document 4, the elastic deformation of the heat sink due to the pressing force applied at an end of the heat sink is in contact with a shoulder portion of the heat generating element, so that the elastic deformation reaches into an inside opposing to the heat generating element; therefore, there is a possibility of bringing about a condition that it rises up at the heat generating element.

### BRIEF SUMMARY OF THE INVENTION

As was mentioned above, the conventional arts have drawbacks, such as, that it must resolve the requirement for the small-sizing and simplification thereof, upon achieving the improvement of cooling capacity, as the cooling apparatus for use in the electronic equipments, etc.

The present invention is accomplished by taking the drawbacks of the conventional arts into the consideration thereof, and an object thereof is to provide a cooling technology for the electronic equipments, for enabling the small-sizing of the electronic equipments while increasing the cooling capacity or performance thereof.

According to the present invention, for dissolving the drawback of the conventional arts mentioned above, there is provided a cooling apparatus for use in electronic equipment, with a liquid cooling method, comprising: a heat receiving member, which is thermally connected with a heat generating body, and which is configured to receive heat by means of a coolant flowing within an inside thereof; and a heat radiating member, which is configured to radiate the heat received within the heat receiving member, wherein the heat receiving member has a plate-like heat receiving base body, which is thermally connected with the heat generating body, and a heat receiving case body, which covers over the heat receiving base body, wherein the body members are joined with, so as to define a sealed space for running the coolant therein. The heat receiving base body is a plate-like member, being made of a metallic material, and being formed with fins, as a unit, for building up flow passages of the coolant, on a plane thereof on a side opposite to a plane, which is thermally connected with the heat generating body. The heat receiving case body is formed with a flow inlet and a flow outlet for running the coolant therein and out, on an upper surface or a side surface thereof, and a plural number of flange-like attaching portions extending nearly perpendicular to the side surface at a lower end portion of the side surface, as a unit. And, the heat receiving member is held opposite to the heat generating body of the electronic equipment, and is thermally connected with the heat generating body, by pressing the heat receiving member onto the heat generating body through an elastic deformation within the attaching portions of the heat receiving case body and the heat receiving case body, thereby achieving the thermal connection therebetween.

Further, according to the present invention, within the cooling apparatus for use in electronic equipment, as described in the above, the deformation within the heat receiving base body due to pressure between the heat generating body is absorbed by an elastic deformation in height direction of the fins, which are formed on the heat receiving base body as a unit.

And further, according to the present invention, within the cooling apparatus for use in electronic equipment, as described in the above, the heat receiving vase body of the heat receiving member, and the attaching portions are made of a resin material being less in permeability of water.

Thus, according to the present invention, with such the structures as was mentioned above, it is possible to provide the cooling apparatus for use in the electronic equipments, being small in the sizes and low in the cost thereof, without necessity of adding any special member for achieving the thermal connection of the heat receiving member onto the heat generating body.

### BRIEF DESCRIPTION OF THE SEVERAL VIEWS OF THE DRAWING

Those and other objects, features and advantages of the present invention will become more readily apparent from the following detailed description when taken in conjunction with the accompanying drawings wherein:

FIG. 1 is an outline structural view for showing an embodiment of electronic equipment, mounting a cooling apparatus therein, according to the present invention;

FIGS. 2A to 2C are views for showing the detailed structures of an example of a heat receiving member, conceptually, according to the present embodiment;

FIGS. 3A and 3B are views for showing the detailed structures of an example of a heat receiving base body, according to the present embodiment; and

FIGS. 4A to 4C are views for showing the condition of achieving thermal connection between a heat generating body and a heat receiving member, according to the present invention.

### DETAILED DESCRIPTION OF THE PREFERRED EMBODIMENTS

Hereinafter, embodiments according to the present invention will be fully explained by referring to the drawings attached herewith.

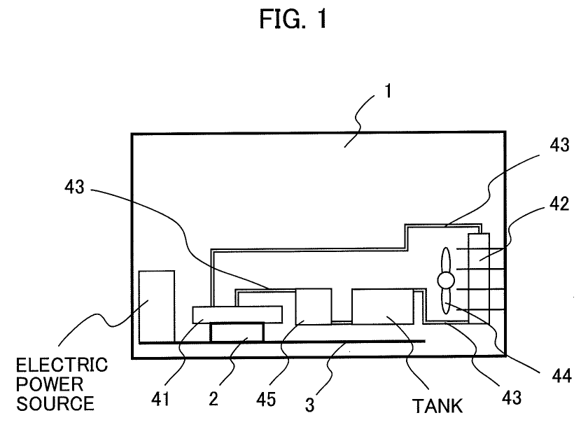

FIG. 1 is an outline structural view for showing an embodiment of the electronic equipment, which mounts a cooling apparatus according to the present invention therein. Within the electronic equipment 1, there is mounted a circuit board 3 mounting a semiconductor integrated circuit 2. For a cooling apparatus 4, according to the present invention is shown a semiconductor integrated circuit (hereinafter, being called “a heat generating body”) 2 as a body to be cooled. The cooling apparatus 4 shown in FIG. 1 applies a cooling method of repeating heat conversion and heat transfer by means of a coolant, by circularly driving the coolant therein, while connecting between a heat receiving member 41 and a heat radiating member 42 by a group of conduits 43, comprises the following components. The heat receiving member 41 of the cooling apparatus 4 is connected is disposed to be thermally connected with the heat generating body 3, so as to transfer the heat of the heat generating body 3 into the coolant flowing therein. The coolant, rising up temperature thereof through the heat conversion from the heat generating body 2, is transferred to the heat radiating member 42 through the group of conduits 43, being driven by a pump 45, which is connected within a circulating flow passage. The heat radiating member 42 is ventilated by a fan 44, etc., and the heat of the coolant flowing therein is transferred to an air ventilated, and thereby to be radiated into the air. The coolant, the temperature of which is lowered through the heat radiation, is driven, circularly. With the circulating passage is connected a tank for accumulating the coolant therein.

Further, within the electronic equipment 1 are mounted members, including a battery, etc. Herein, the electronic equipment 1 is, for example, a personal computer, a television apparatus, a liquid crystal projector, etc., but it should not be limited to a specific one. Also, the heat generating body 2, as the body to be cooled, may be other one than the semiconductor integrated circuit mounted on the circuit board 3, and it may be a disc drive, for example. Thus, according to the present embodiment, the heat generating body 2 should not be restricted only to the semiconductor integrated circuit.

Next, detailed explanation will be made on the heat receiving member 41 of the cooling apparatus 4, according to the present invention.

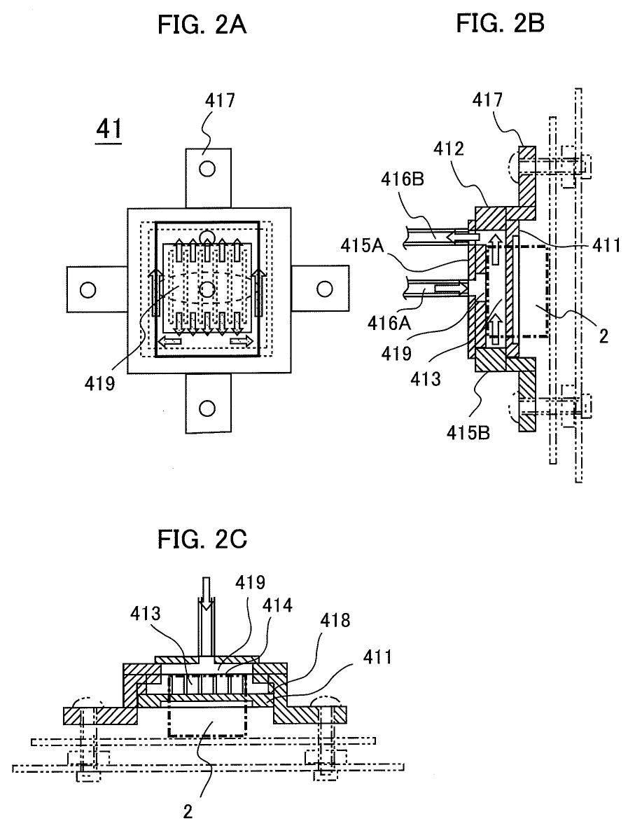

FIGS. 2A to 2C are views for showing the structures of the heat receiving member, according to an embodiment of the present invention, conceptually. In FIGS. 2A to 2C, the heat receiving member 41 is made by joining a heat receiving base body 411 and a heat receiving case body 412, while forming a flow space 413 for the coolant within an inside thereof.

On the heat receiving base body 411 of the present embodiment are formed fins 414 for defining flow paths of the coolant within the flow space 413. The fins 414 (the details thereof will be mentioned later) are formed to be thin in the thickness thereof through the skiving or the like, i.e., in the shape having a height higher than the flow space 413 for the coolant, together with the heat receiving base body 411 as a unit. Also, the fins 414 are formed in a large number thereof at a fine pitch, so as to increase the contact areas thereof; however in FIGS. 2A to 2C, the fins 414 are described by omitting a part of the number of the fins 414, for the purpose of easily understanding the explanation of the flow paths.

Also, upon an upper surface 415A of the heat receiving case body 412, according to the present embodiment, are provided a flow inlet 416A and a flow outlet 416B for the coolant. Further, on a lower end potion of a side surface 415B of the heat receiving case 412 are provided a plural number of attaching members 417, each extending outside in part thereof, like an ear.

The heat receiving base body 411 and the heat receiving case body 412 are fixed with, abutting an upper plane surface of the heat receiving base body 411 on a shoulder portion 418 of an interior wall of the heat receiving case body 412, through an adhering member, etc.

Next, explanation will be made on the flowing condition of the coolant within the heat receiving member 41. The coolant, which is circularly driven by the pump 45, flows from the flow inlet 416A for the coolant, which is provide at a central portion of the upper surface 415A connected with the conduit 43, into the flow space 413 within an inside of the heat receiving member 41. The coolant flowing therein spreads to an upper portion of the fins 414 within a header portion 419 for the coolant, which is provided on the upper surface 415A, and is distributed into arrows (an outlined and a painted out (or solid)), as the flow paths defined between the fins 414. The coolant flowing into a direction of the painted out arrow runs along an external wall of the flow space 413, and joins with the coolant flowing into the direction of the outlined arrow, thereby flowing out, through the flow outlet 416B, from the heat receiving member 41.

Herein, the heat of the heat generating body 2 is transferred to the heat receiving base member 411, which is thermally connected with the heat generating body 2, and further transferred to the fins 414. The coolant running between the fins 414 absorbs the heat of the heat generating body 2, which is transferred from the fins 414. Accordingly, the heat generating body 2 is cooled through the heat conversion between the coolant.

Herein, the heat conversion capacity or performance of the heat generating body 2 is influenced by the thermal connection condition between the heat generating body 2 and the heat receiving member 411. Thus, the thermal connection condition between the heat generating body 2 and the heat receiving member 411 is, preferably, in contact without a gap, such as, an air, etc., between them, and explanation will be made hereinafter, about the structures for obtaining an improvement of the thermal connection therebetween.

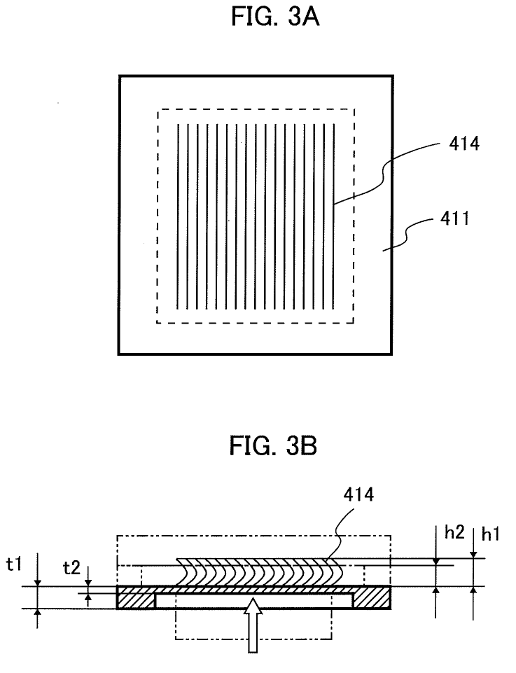

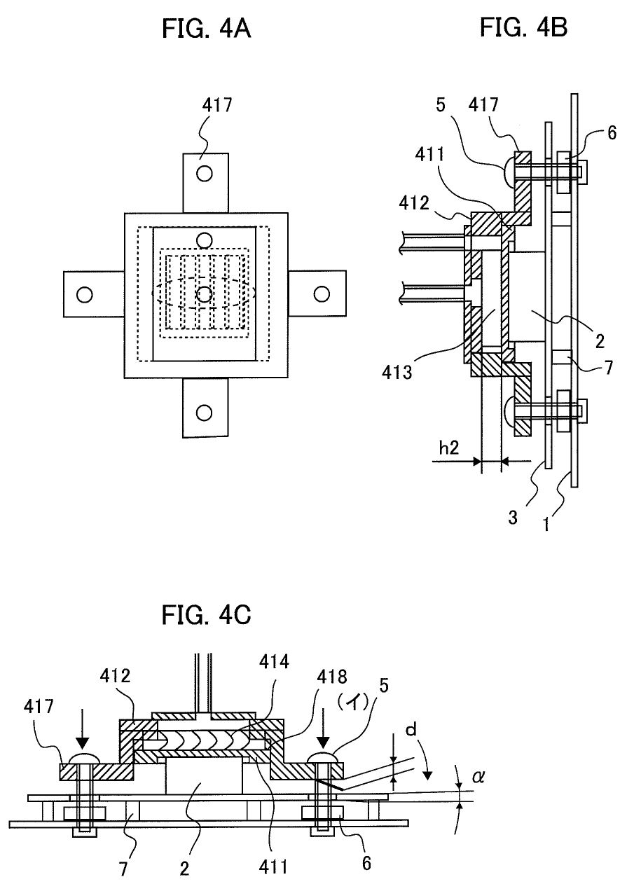

FIGS. 3A and 3B are views for showing the outline structures of an embodiment of the heat receiving base body, according to the present embodiment. FIGS. 4A to 4C are views for showing the structures of the heat generating body and the heat receiving member, according to the present embodiment, under the condition that they are thermally connected with each other. The heat receiving base body 411 shown in FIGS. 3A and 3B is in the shape of a flat plate, being made of a metal material having a superior heat conductivity, and it is formed with such thickness (t1) to have a predetermined rigidity or stiffness. However, from a viewpoint of the heat conductivity from a heat receiving surface of the heat receiving base body 411 to the fins 414, it is preferable that the thickness of the heat receiving base body 411 is as thin as possible. Therefore, at least within an area to be thermally connected with the heat generating body 2, it is preferable that the thickness thereof is thin (t2: t2<t1). Also, within the area, where the thickness thereof is made thin, it is preferable that the fins are formed therein. Within FIGS. 3A and 3B, though the thin thickness (t1) is achieved by digging down on the plane of the side contacting with the heat generating body 2, but it is also possible to achieve the thin thickness (t1) by digging down on the plane of the side forming the fins 414 thereon.

When obtaining the thermal connection between the heat receiving member 41 and the heat generating body 2, since the elastic deformation is generated in the thin thickness portion by the force pressing onto the heat receiving base member 411, therefore preferable thermal connection can be obtained between the heat receiving member 41 and the heat generating body 2.

Herein, as was mentioned previously, the fins 414 are built up, with a fin thickness of about 0.several mm and at a pitch of less than 1 mm, by slicing or cutting off the base member, through the skiving. For this reason, the heat conductivity from the heat generating body 2 to the fins 414 is increased while maintaining the contact area with the coolant, and thereby increasing the capacity or performance of the thermal conversion.

On the other hand, since the fins 414 are formed under the condition of cutting off in the skiving, they may be formed to be under curling a little bit or to have variability or fluctuation in the height thereof. Therefore, the height (h1) of the fins 414 are formed to be higher than the height (h2) of the flow space 413 for the coolant (h1>H2), which is defined by the heat receiving case body 412 and the heat receiving base body 411 as shown in FIGS. 4A to 4C, with this, the fins are held between them, under the condition of being pressed by an upper plane of an opposite interior wall of the heat receiving case body 412. With such the structures, the flow passages are formed, without leakage of the coolant therefrom, in spite of the cases where the fins 414 have the variability or fluctuation of the height when being formed.

Following to the above, explanation will be made on the structures for the thermal connection between the heat receiving member 41 and the heat generating body 2. As shown in FIGS. 4A to 4C, first of all, the heat receiving member 41 has the heat receiving case body 412 and the heat receiving base body 411, and wherein they are joined by a joining member through a shielding member not shown in the figure, which are put between the shoulder portion 418 of the interior wall of the heat receiving case body 412 and the plane of the heat receiving base body 411, on the side of which the fins 414 are formed, or they are adhered fixedly as a unit through an adhesive material or the like. The heat receiving member 41 is held on a housing of the electronic equipment 1 or a fixing member 6 provide on the housing, etc., abutting the heat receiving base body 411 onto the heat generating body 2, which is mounted on the circuit board 3, at the attaching members 417 of the heat receiving case body 412 extending like an ear, into the direction of an arrow A by means of a plural number of screws 5.

Herein, the circuit board 3 is held to be mounted on a plural number of holding members 7, which are provided on the housing of the electronic equipment 1 or the like. In this instance, for example, in case where the circuit board 3 is deformed, or if the plural number of holding (or fixing) members have the variability or fluctuation of the height, then the circuit board 3 results in being held to have an inclination (“α” degree), for example, with respect to the housing of the electronic equipment 1. In order to connect the heat generating body 2 and the heat receiving member 41, thermally, under this condition, first of all, the heat receiving member 41 must be adjusted in the height thereof to be inclined by “α” degree, by means of a predetermine one of the plural number of screws 5. Clamping of the screws 5 are done, after bringing the heat receiving member 41 to be in the condition of contacting with the heat generating body 2 with adjusting the inclination of the heat receiving member 41, by further clamping the screws, thereby obtaining a pressing force for achieving the thermal connection between the heat receiving base body 411 and the heat generating body 2. A clamping stroke (d) of screw, necessary for obtaining a predetermined pressing force of the heat receiving base body 411 towards the heat generating body, is obtained by the elastic deformation of the attaching members 417. Therefore, the heat receiving case body 412, being formed with the attaching members 417 as a unit, is made of a resin material, which can produce a desired amount of elastic deformation. On the other hand, since it is also a member for running the coolant therein, it is desired for the resin material to have a less permeability of water.

Herein, the pressing force due to the elastic deformation of the attaching members 417 of the heat receiving case body 412 pushes the plane of the heat receiving base body 411, which is in contact with shoulder portion 418 of the interior wall of the heat receiving case body 412, onto the heat generating body 2. However, the elastic deformation of the attaching members 417 of the heat receiving case body 412 reaches to the side wall 415 of the heat receiving case body 412, etc., but because the heat receiving case body 412 and the heat receiving base body 411 are joined by a member separating therefrom, i.e., the joining member, it restrains the elastic deformation of the attaching members 417 from influencing to the deformation of the heat receiving base member 411 at the portion contacting with the heat generating body 2. This indicates that it is possible to maintain the thermal connection between the heat receiving member 41 and the heat generating body 2, in spite of the deformation of the attaching members 417.

Furthermore, by making the thermal connecting area between the heat receiving base body 411 and the heat generating body 2 to be thin in the thickness thereof, if the elastic deformation is generated on the plane portion of the heat receiving base body 411, opposite to the heat generating body 2, within the area where the heat receiving base body 411 is connected with the heat generating body 2 due to the pressing force by means of the screws 5, but with the buckling deformation of the fins 414, which are provided on the opposite side plane of the heat receiving base body 411, in the height direction, it is possible keep the flow passage of the heat receiving member 41.

As was mentioned above, within the heat receiving member 41, being formed by joining the heat receiving base body 411 and the heat receiving case body 412, the thermal connection between the heat generating body 2 and the heat receiving member 41 is achieved through mutual elastic deformations of the both members, and therefore, it is possible to achieve a stable thermal connection therebetween; i.e., enabling to provide the heat receiving member of the cooling apparatus for use in electronic equipments, being small in the sizes and low in the cost thereof.

Also, by forming the portion of the heat receiving base body 411, on which the fins 414 are formed, to be thin in the thickness thereof, since the height of piling up the heat generating body 2 and the heat receiving member 41 can be reduced, therefore it is preferable for thin thickness of the electronic equipments.

While we have shown and described several embodiments in accordance with our invention, it should be understood that disclosed embodiments are susceptible of changes and modifications without departing from the scope of the invention. Therefore, we do not intend to be bound by the details shown and described herein but intend to cover all such changes and modifications that fall within the ambit of the appended claims.

What is claimed is:

1. A cooling apparatus for use in electronic equipment, with a liquid cooling method, comprising:
a heat receiving member, which is thermally connected with a heat generating body, and which is configured to receive heat by means of a coolant flowing within an inside thereof; and
a heat radiating member, which is configured to radiate the heat received within said heat receiving member, wherein
said heat receiving member has a plate-like heat receiving base body, which is thermally connected with said heat generating body, and a heat receiving case body, which covers over said heat receiving base body, wherein said body members are joined with, so as to define a sealed space for running the coolant therein,
said heat receiving base body is a plate-like member, being made of a metallic material, and being formed with fins, as a unit, for building up flow passages of said coolant, on a plane thereof on a side opposite to a plane, which is thermally connected with said heat generating body,
said heat receiving case body is formed with a flow inlet and a flow outlet for running the coolant therein and out, on an upper surface or a side surface thereof, and a plural number of flange-like attaching portions extending nearly perpendicular to the side surface at a lower end portion of the side surface, as a unit, and
said heat receiving member is held opposite to said heat generating body of said electronic equipment, and is thermally connected with said heat generating body, by pressing said heat receiving member onto said heat generating body through an elastic deformation within said attaching portions of said heat receiving case body and said heat receiving case body.

2. The cooling apparatus for use in electronic equipment, as described in the claim 1, wherein the deformation within said heat receiving base body due to pressure between said heat generating body is absorbed by an elastic deformation in height direction of said fins, which are formed on said heat receiving base body as a unit.

3. The cooling apparatus for use in electronic equipment, as described in the claim 1, wherein said heat receiving vase body of said heat receiving member, and said attaching portions are made of a resin material being less in permeability of water.

4. The cooling apparatus for use in electronic equipment, as described in the claim 2, wherein
said heat receiving vase body of said heat receiving member, and said attaching portions are made of a resin material being less in permeability of water.
